(19) United States
(12) Patent Application Publication
(10) Pub. No.: US 2025/0237699 A1
(43) Pub. Date: Jul. 24, 2025

(54) TIME-ALIGNED RF ANALYSIS FROM GEOGRAPHICALLY DISTRIBUTED RECEIVERS

(71) Applicant: Tektronix, Inc., Beaverton, OR (US)

(72) Inventors: Alejandro C. Buritica, Georgetown, TX (US); Donald J. Dalebroux, Vernonia, OR (US); Alexander Krauska, Beaverton, OR (US); Christopher N. White, Cedar Park, TX (US)

(21) Appl. No.: 19/029,348

(22) Filed: Jan. 17, 2025

Related U.S. Application Data
(60) Provisional application No. 63/622,282, filed on Jan. 18, 2024.

(51) Int. Cl. G01R 31/317; G01R 31/28

(52) U.S. Cl. CPC G01R 31/31725; G01R 31/2822; G01R 31/31727

(57) ABSTRACT

Systems and methods for capturing a test signal through multiple signal sensors and thereafter time-aligning and displaying time-aligned samples of the test signal are disclosed. Multiple signal sensors may be distributed at different geographical locations, each signal sensor including a sample counter that sequentially generates sample counts that are used in generating internal time stamps for samples of the test signal acquired by the signal sensor. Each signal sensor receives a general reference clock signal that enables samples of the test signal from the multiple signal sensors to be time-aligned. A timing offset between an internal time stamp associated with a transition of the general reference clock signal and internal time stamps associated with samples of the test signal is determined for each signal sensor. The timing offsets enable samples of the test signal from the multiple signal sensors to be aggregated, time-aligned, and the time-aligned samples displayed for analysis.

### CROSS-REFERENCE TO RELATED APPLICATIONS

This disclosure is a non-provisional of and claims benefit from U.S. Provisional Application No. 63/622,282, titled “TIME-ALIGNED RF ANALYSIS FROM GEOGRAPHICALLY DISTRIBUTED RECEIVERS,” filed on Jan. 18, 2024, the disclosure of which is incorporated herein by reference in its entirety.

### TECHNICAL FIELD

This disclosure relates generally to the capture and analysis of radio frequency (RF) signals, and more specifically to a system and method for synchronizing or time-aligning RF signals captured by multiple signal sensors, which may be located in different geographical locations.

### BACKGROUND

The synchronization or time-alignment of electrical signals is useful in many different contexts, such as where an electrical signal is being sampled or acquired at different geographical locations or is being acquired at the same geographical location but by multiple signal sensors. In a military environment, for example, multiple signal sensors, such as spectrum analyzers, may be geographically distributed at different locations in a test range to acquire a radar signal being transmitted from a signal source like a military airplane or other piece of military equipment. Another example environment is in a test lab setting where different portions of the spectrum of an RF test signal are to be tested using multiple signal sensors, each signal sensor capturing a different portion of the spectrum of the RF test signal. In each of these situations, synchronizing or time-aligning the multiple samples or acquisitions of the RF test signal captured or acquired by each of the different signal sensors increases the quality of the signal analysis compared to analyzing non-aligned samples. There is thus a need for systems and methods to capture and analyze RF test signals by multiple signal sensors and time-align these captured signals to provide a time-aligned multi-channel visualization of the RF test signal being analyzed.

### BRIEF DESCRIPTION OF ACCOMPANYING DRAWINGS

FIG. 1 is a block diagram of a test and measurement system including multiple signal sensors for capturing a radio frequency (RF) test signal and a sensor signal integration device coupled to the multiple signal sensors to aggregate, time-align, and display the time-aligned captured RF test signal from the multiple signal sensors for analysis in accordance with embodiments of the disclosure.

FIG. 2 is a signal timing diagram illustrating the utilization of sample counts generated by a sample counter contained in each of the multiple signal sensors of FIG. 1 to generate time stamps for samples of the RF test signal and a general reference clock signal supplied to each of the signal sensors for use in time-aligning the samples of the RF test signal acquired by the multiple signal sensors in accordance with embodiments of the present disclosure.

FIG. 3 is a block diagram of a test and measurement system including multiple geographically distributed signal sensors for capturing a radio frequency RF test signal and a sensor signal integration device coupled to the multiple signal sensors to aggregate, time-align, and display the time-aligned captured RF test signal in accordance with embodiments of the disclosure.

FIG. 4 is a flowchart illustrating an example process of capturing, time-aligning, and displaying samples of an RF test signal from multiple signal sensors in accordance with embodiments of the present disclosure.

### DESCRIPTION

Embodiments of the present disclosure are directed to systems and methods for capturing a radio frequency (RF) test signal through multiple signal sensors and thereafter time-aligning and displaying time-aligned samples of the RF test signal for analysis. The multiple signal sensors, which may be spectrum analyzers in embodiments, may be distributed at different geographical locations. In embodiments, each of the signal sensors includes a free-running sample counter that sequentially generates sample counts which, in turn, are used in generating internal time stamps for samples of the RF test signal acquired by the signal sensor. Each of the signal sensors is coupled to a general reference clock signal that enables acquisitions or samples of the RF test signal from the multiple signal sensors to be synchronized or time aligned. A timing offset between an internal time stamp associated with a transition of the general reference clock signal and internal time stamps associated with samples of the RF test signal is determined and these timing offsets enable the samples of the RF test signal from the multiple signal sensors to be aggregated, synchronized or time-aligned, and the time-aligned samples displayed for further analysis.

In embodiments of the disclosure, a system includes a plurality of signal sensors, each of the signal sensors configured to generate waveform samples from the signal received by the signal sensor and to associate an internal time stamp with each waveform sample of the test signal. Each of the plurality of signal sensors is further configured to receive a general reference clock signal and to associate an internal time stamp with a transition of the general reference clock signal. The general reference clock signal may, for example, be a signal in a Global Navigation Satellite System (GNSS) system, which includes the Global Positioning System (GPS) in the United States or the GLONASS system in Russia, Galileo system in the European Union, or BeiDou system in China. The internal time stamps of each of the plurality of signal sensors are independent of the internal times stamps of the other signal sensors. In embodiments, each signal sensor includes a free-running counter that sequentially generates sample counts that are used in generating the internal time stamps for samples of the test signal. An integration device is coupled to the plurality of signal sensors and includes a signal sensor analyzer configured to time-align the samples from the plurality of signal sensors based on a timing offset determined for each signal sensor from the corresponding internal time stamp associated with the reference clock signal and internal time stamps associated with the corresponding samples of the test signal. The integration device is further configured to display the time-aligned samples of the test signal based on the determined timing offsets. In embodiments, the integration device is coupled to the plurality of signal sensors through a suitable network, such as a network including the Internet or through a wireless network. The integration device may be a computer and the signal sensor analyzer software that is executed by one or more processors of the computer.

In embodiments, each of the signal sensors includes a sample counter configured to sequentially generate sample counts in response to an internal clock signal. The generated sample counts are then utilized in generating corresponding internal time stamps. In some embodiments, each sample count may be utilized as a corresponding internal time stamp. In some embodiments, the sample counter is a free-running timer having a sufficiently large count to enable the sample counter to run for a very long period of time without reaching a maximum count of the sample counter. For example, in an embodiment, the sample counter is a free-running 64-bit counter that is clocked by a 5 Gigahertz (GHz) internal clock signal. The counter is “free running” meaning that upon power up of the signal sensor containing the counter, the counter is continuously clocked by the 5 GHz internal clock signal until power is lost.

A free-running 64-bit sample counter such as that described above allows for slightly over one million hours of range or operation time before the counter reaches the maximum count value of the counter. Thus, the sample counter generates an extremely large number of unique sample counts that may be utilized in generating corresponding unique internal time stamps. In embodiments, each sample count generated by the sample counter is used directly as a corresponding internal time stamp when samples of a test signal are being acquired. Such a 64-bit sample counter provides 0.2 nanoseconds (ns) of resolution for the counter. This is true because the 5 GHz internal clock signal provides 0.2 ns resolution since the period of this clock signal is 0.2 ns, meaning a new sample count is generated by the sample counter every 0.2 ns. Test and measurement instruments like spectrum analyzers and oscilloscopes typically include such free-running counters for use in generating internal time stamps, and embodiments of the present disclosure enable such sample counters and associated internal time stamps to be utilized in combination with a general clock reference signal, such as a GNSS signal, to synchronize or time-align samples of a test signal acquired by multiple signal sensors. The sample counter may have more or fewer bits or be clocked at a different rate than described above in other embodiments.

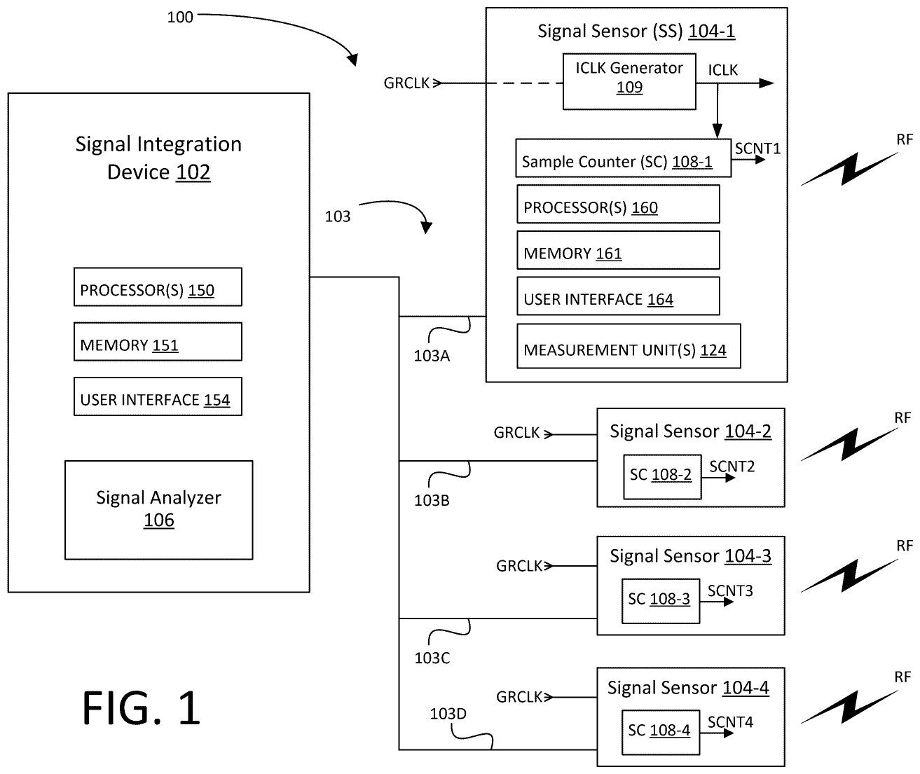

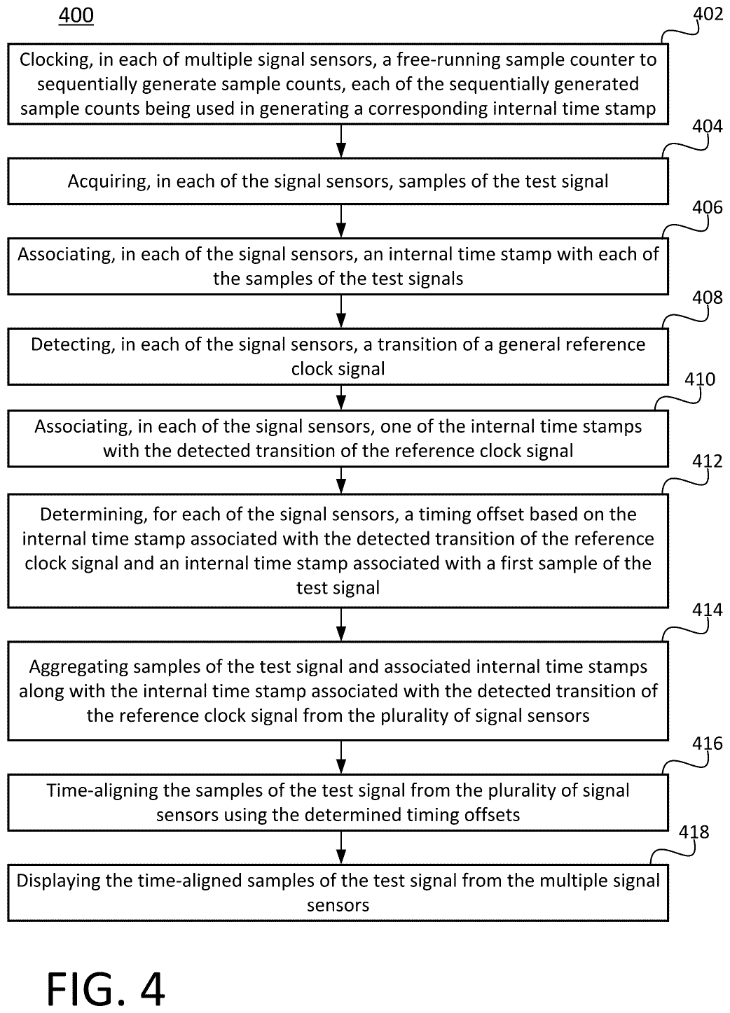

FIG. 1 is a block diagram of a test and measurement system 100 including a signal integration device 102 coupled through a network 103 to multiple signal sensors 104-1 to 104-4 and including a signal analyzer 106 for capturing samples of a radio frequency (RF) test signal, labeled “RF” in FIGS. 1 and 4, through the multiple signal sensors and aggregating and time-aligning these samples on the integration device to allow for display and analysis of the test signal in accordance with embodiments of the present disclosure. In embodiments, each of the individual signal sensors 104-1 to 104-4 may generate samples from different portions of the RF test signal, such as different or overlapping frequency bands of the RF signal. Each of the signal sensors 104-1 to 104-4 includes a sample counter 108-1 to 108-4 configured to generate sequential sample counts SCNT1-SCNT4 that are used in generating internal time stamps for samples of the RF test signal, as described in more detail below. The signal integration device 102 further includes one or more processors 150 that may be configured to execute instructions from a memory 151 and may perform any methods and/or associated operations corresponding to such instructions. A user interface 154 is coupled to the one or more processors 150 and may include, for example, a keyboard, mouse, touchscreen, output display, file storage, and/or any other controls employable by a user to interact with the signal integration device 102. In some embodiments, the user interface 154 may be connected to or controlled by a remote interface (not illustrated) so that a user may alternately control operation of the signal integration device 102 from a remote location physically away from the device. The test and measurement system 100 includes the four signal sensors 104-1 to 104-4 by way of example, while systems according to embodiments of the disclosure may include more or fewer signal sensors.

A display portion of the user interface 154 may be a digital screen such as an LCD, LED, or any other monitor to display waveform samples of the time-aligned samples of the RF test signal generated by the signal analyzer 106. The operation of the signal analyzer 106 in aggregating, time-aligning, and displaying samples of the RF test signal from the signal sensors 104-1 to 104-4 is described in more detail below. The display portion of the user interface 154 may also display additional data, information, and various operation menus to a user of the signal integration device 102. In some embodiments, a main output display of the user interface 154 may be located remotely from the signal integration device 102 or display information may be sent to a remote device for viewing or performing measurement and analysis. In embodiments of the disclosure, the signal integration device 102 may be a computer, such as a laptop, tablet, or desktop personal computer, or a test and measurement device.

Each of the sample counters 108-1 to 108-4 is configured to sequentially generate the corresponding sample counts SCNT1-SCNT4 in response to an internal clock signal ICLK, which is shown only for the signal sensor 104-1. An internal clock signal (ICLK) generator 109 (shown only for signal sensor 104-1) generates the internal clock signal ICLK and embodiments of this generator are described in more detail below. In FIG. 1, additional components contained in each of the signal sensors 104-1 to 104-4 are illustrated only for the signal sensor 104-1. These additional components include one or more processors 160 that may be configured to execute instructions from a memory 161 to perform any methods and/or associated operations corresponding to such instructions. A user interface 164 may perform the same or similar function as the user interface 154, described above, enabling the user to control and interact with the signal sensor 104. In some embodiments the user interface 164 is a remote interface so that a user may alternately control operation of the signal sensor 104 from a remote location physically away from the device. Each signal sensor 104-2 to 104-4 also includes these additional components but the components are not illustrated in FIG. 1 to simplify the figure. As mentioned above, the signal sensors 104-1 to 104-4 produce sample counts SCNT1-SCNT4 by independently operating their sample counters 108-1 to 108-4, respectively. These sample counts SCNT1-SCNT4 are then utilized in generating corresponding internal time stamps for samples of the RF test signal captured by each of the signal sensors 104-1 to 104-4. Each sample counter 108-1 to 108-4 is a free-running timer having a sufficiently large sample count SCNT1-SCNT4 (i.e., the sample count has a sufficiently large number of bits) to enable the sample counter to run for a very long period, such as many hours or years without reaching a maximum value of the sample count SCNT1-SCNT4 of the sample counter. This configuration allows unique internal time stamps to be generated from the sample counts SCNT1-SCNT4 from a time the signal sensors 104-1 to 104-4 are individually powered to many years or decades in the future. The sample counters 108-1 to 108-4 may, for example, be a free-running 64-bit counter and that is clocked by a 5 Gigahertz (GHz) internal clock signal ICLK, which provides approximately a million hours of range or operational time before the maximum count of each sample counter is reached, although counters of other sizes or clock rates may also be used.

The sample count SCNT1-SCNT4 generated by each of the sample counters 108-1 to 108-4 is independent of the sample counts generated by any and all of the other sample counters 108-1 to 108-4. As a result, the internal time stamps for the samples of the RF test signal captured by each of the signal sensors 104-1 to 104-4 are also independent of the internal time stamps of the samples of the other ones of the signal sensors. For example, the sample count SCNT1 generated by the sample counter 108-1, and the corresponding internal time stamps generated therefrom, are independent of the sample counts SCNT2-4 generated by the sample counters 108-2 to 108-4. The sample counters 108-1 to 108-4 are free-running counters that generate independent sample counts SCNT1-SCNT4.

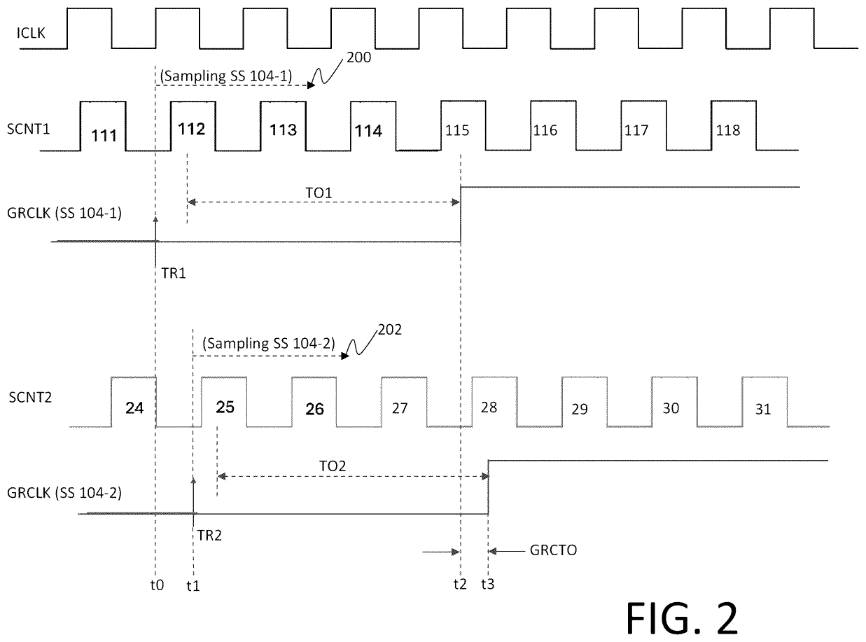

Due to the independence of the sample counters SCNT1-SCNT4 and corresponding internal time stamps generated therefrom, a means of synchronizing or time-aligning the samples of the RF test signal captured by each of the signal sensors 104-1 to 104-4 is used to align the samples to one another. To enable time-alignment of the samples of the RF test signal captured by the signal sensors 104-1 to 104-4, a global reference clock signal GRCLK is supplied to each signal sensor in the test and measurement system 100. The global reference clock signal GRCLK may be, for example, a Global Navigation Satellite System (GNSS) signal such a Global Positioning System (GPS) clock signal in the United States, or a GLONASS clock signal in Russia, a Galileo clock signal in the European Union, or a BeiDou clock signal in China. Typically, the general reference clock signal GRCLK may be a suitable GNSS clock signal when the signal sensors 104-1 to 104-4 are not positioned in the same location but are geographically distributed, as described in more detail below with reference to FIG. 2.

The general reference clock signal GRCLK may also be provided from a different source through a signal distribution system that is coupled to each of the signal sensors 104-1 to 104-4. Such a signal distribution system is not shown in FIG. 1 but may include wires, coaxial cables, fiber optic cables, or other suitable transmission media to couple the general reference clock signal GRCLK to each of the signal sensors 104-1 to 104-4. A signal distribution system may typically be utilized in an environment such as in a test lab where all the signal sensors 104-1 to 104-4 are positioned in the same physical location. The example embodiment of the test and measurement system 100 of FIG. 1 shows the network 103 coupling the signal integration device 102 to these signal sensors 104-1 to 104-4 through individual network segments 103A-103D. This type of network allows each of the signal sensors 104-1 to 104-4 to communicate captured samples of the RF test signal and associated internal time stamps for these samples along with other information directly to the signal integration device 102 to allow the for the aggregation and time-aligning of the samples from all the signal sensors 104-1 to 104-4, as described in more detail below. In other embodiments, such as a lab setting, the network 103 may be implemented as a daisy-chain type network, where each of the signal sensors 104-1 to 104-4 are coupled to one another and to the signal integration device 102 as individual nodes on a daisy-chain network.

The overall operation of the test and measurement system 100 is described with reference to FIGS. 1 and 2. FIG. 2 is a signal timing diagram illustrating example sample counts SCNT1-SCNT4 generated by the sample counters 108-1 and 108-2 contained in the signal sensors 104-1 and 104-2 along with the assignment or association of an internal time stamp with each transition of the global clock reference signal GRCLK received by each of the signal sensors. In the following description, the sample counts SCNT1-SCNT4 may be referred to generally as sample count SCNT when referencing any of these sample counts, with a particular sample count being referred to when necessary for the purposes of the description. The same is true for the sample counters 108-1 to 108-4 and the signal sensors 104-1 to 104-4, which may be referred to generally as sample counter or counters 108 and signal sensor or sensors 104, respectively.

FIG. 2 shows in the topmost signal diagram the internal clock signal ICLK that is applied to clock each of the sample counters 108 in the signal sensors 104. Only the single internal clock signal ICLK is shown in FIG. 2 by way of example and to simplify the figure. Although only the single ICLK signal is shown in FIG. 2, each signal sensor 104 generates a separate, independent, internal clock signal ICLK that is used to clock the corresponding sample counter 108 within each signal sensor 104-1 to 104-4. Furthermore, in FIG. 2 only the sample counts SCNT1 and SCNT2 generated by the sample counters 108-1 and 108-2 in the signal sensors 104-1 and 104-2 are shown by way of example. The sample counters 108-3 and 108-4 in signal sensors 104-3 and 104-4 operate in the same way and thus this operation can be understood in view of the description of FIGS. 1 and 2, and accordingly the detailed operation of sample counters 108-3 and 108-4 is not separately described in more detail herein.

In operation, each of the free-running sample counters 108-1, 108-2 is clocked by a corresponding internal clock signal ICLK and sequentially generates sample counts SCNT1, SCNT2. The sequential sample counts SCNT1 generated by the sample counter 108-1 are shown in FIG. 2 along with example values for the illustrated sample counts. In the example of FIG. 2, the sample counts 111-118 are sequentially generated by sample counter 108-1. The sample counts 24-31 are sequentially generated by sample counter 108-2. In embodiments of the system 100, the sample counts SCNT generated by the sample counters 108 may be used directly as corresponding internal time stamps for samples of the RF test signal being acquired by each of the signal sensors. Accordingly, in the following description the terms sample counts SCNT and internal time stamps may be used interchangeably. Thus, the sample counts 111-118 generated by sample counter 108-1 may be alternately referred to as sample counts or internal time stamps in the following description. The same is true for the sample counts 24-31 generated by sample counter 108-2, which may be alternately referred to as sample counts or internal time stamps.

In operation, the signal sensors 104 begin acquiring the RF test signal (FIG. 1) in response to detection of an event trigger TR defined or configured for the RF test signal in each signal sensor 104. The event trigger TR may vary in different embodiments of the disclosure. For example, the event trigger TR may be edge triggering where, upon detection of transition of the RF test signal from a first level to a second level (i.e., an edge), the signal sensors 104 begin capturing or acquiring samples of the test signal. Other types of event triggers TR such as envelope triggering or modulation triggering may be utilized to configure each of the signal sensors 104 to trigger or begin acquiring the RF test signal. FIG. 2 shows a first event trigger TR1 for the RF test signal being received by the signal sensor 104-1 occurs at a time t0. After detection of the first event trigger TR1 at time t0, the signal sensor 104-1 begins acquiring samples of the RF test signal, as represented in FIG. 2 by an arrow 200 labelled “Sampling SS 104-1” where the abbreviation “SS” stands for “signal sensor.” A second event trigger TR2 for the RF test signal being received by the signal sensor 104-2 occurs at a time t1, and after detection of the second event trigger TR2 at time t1, the signal sensor 104-2 begins acquiring samples of the RF test signal, as represented in FIG. 2 by an arrow 202 labelled “Sampling SS 104-2.” Each of the signal sensors 104 includes appropriate circuitry, which is part of the part of measurement units 124 (see FIG. 1), that may be configured to detect the desired type of event trigger TR and thereafter initiate acquisition of the RF test signal. The time difference between the first and second triggers TR1, TR2 may, for example, be due to the signal sensor 104-2 being physically located a greater distance from a source of the RF test signal than is the first signal sensor 104-1, as described in more detail below.

As each signal sensor 104-1, 104-2 acquires the RF test signal after detection of the event trigger TR1, TR2, samples of the test signal are saved and an internal time stamp SCNT is assigned or associated with each sample. Thus, in the example of FIG. 2, a first sample of the RF test signal acquired by the signal sensor 104-1 is assigned an internal time stamp (i.e., SCNT1) value of 112, the next sample is assigned an internal time stamp of 113, and so on for sequential samples and sequential internal time stamps through the value 118 in the example shown in FIG. 2. Similarly, a first sample of the RF test signal acquired by the signal sensor 104-2 is assigned an internal time stamp (i.e., SCNT2) value of 25, the next sample is assigned an internal time stamp of 26, and so on for sequential samples and sequential internal time stamps through the value 31 in the example shown in FIG. 2.

Each of the signal sensors 104-1, 104-2 also receives the general reference clock signal GRCLK, which may be referred to as the “GRCLK signal” in the following description. The GRCLK signal received by the signal sensor 104-1 is indicated with the parenthetical (SS 104-1) and the GRCLK signal received by the signal sensor 104-2 is indicated with the parenthetical (SS 104-2) in FIG. 2. Ideally, the GRCLK signal is received by each signal sensor 104 at the same time, meaning that each transition of the GRCLK is received by each signal sensor at the same time. This is not true in the example of FIG. 2 and may not be true in implementations of the test and measurement system 100 for a variety of reasons, as discussed in more detail below. When each signal sensor 104 detects an edge or transition of its local GRCLK signal, the signal sensor associates an internal time stamp (i.e., SCNT in the example of FIG. 2) with the detected transition. Thus, in the example of FIG. 2 a transition of the GRCLK signal received by the signal sensor 104-1 occurs at a time t2 and the signal sensor 104-1 associates the internal time stamp 115 with this detected transition. A transition of the GRCLK signal received by the signal sensor 104-2 occurs at a time t3 and the signal sensor 104-2 associates the internal time stamp 28 with this detected transition. The internal time stamps 115 and 28 associated with detected transitions of the GRCLK signal received by the signal sensors 104-1, 104-2 allows for synchronization or time-aligning of the samples of the RF test signal captured by the signal sensors 104, as described in more detail below.

Once each signal sensor 104 has detected an event trigger, acquired samples of the RF test signal after detection of the trigger event, and detected a transition of the GRCLK signal received by the signal sensor, these samples and time stamps are communicated over the network 103 to the integration device 102. In embodiments of the test and measurement system 100, the samples of the RF test signal are in-phase (I) and quadrature (Q) data for the samples of the RF test signal. In such an embodiment each sample includes corresponding IQ data for the RF test signal and this IQ data along with the internal time stamp for each sample of IQ data and the internal time stamp associated with the detected transition of the received GRCLK signal are communicated over the network 103 to the signal integration device 102.

In the integration device 102, the signal analyzer 106 calculates a timing offset TO for the samples from each of the signal sensors 104 using the corresponding internal time stamp SCNT associated with the GRCLK signal and the internal time stamps SCNT associated with the corresponding samples of the RF test signal. In the example of FIG. 2, the signal analyzer 106 calculates a first timing offset TO1 for the signal sensor 104-1. The signal analyzer 106 determines the timing offset TO1 by subtracting the difference between the internal time stamp 115 associated with the GRCLK signal received by signal sensor 104-1 and the internal time stamps associated with the samples of the RF test signal after detection of the event trigger TR1. More specifically, in the embodiment of FIG. 2 the signal analyzer 106 determines the timing offset TO1 by subtracting the difference between the internal time stamp 115 and the internal time stamp 112 associated with the first sample of the RF test signal after detection of the event trigger TR1. In the same way, the signal analyzer 106 determines the timing offset TO2 for the signal sensor 104-2 by subtracting the difference between the internal time stamp 28 associated with the GRCLK signal received by signal sensor 104-2 and the internal time stamp 25 associated with the first sample of the RF test signal after detection of the event trigger TR2. The time interval between consecutive internal time stamps (e.g., 0.2 ns where the ICLK signal is a 5 GHz clock signal) is known and thus the differences in internal time stamps corresponds to a determinable period of the time in the form of the timing offsets TO1, TO2.

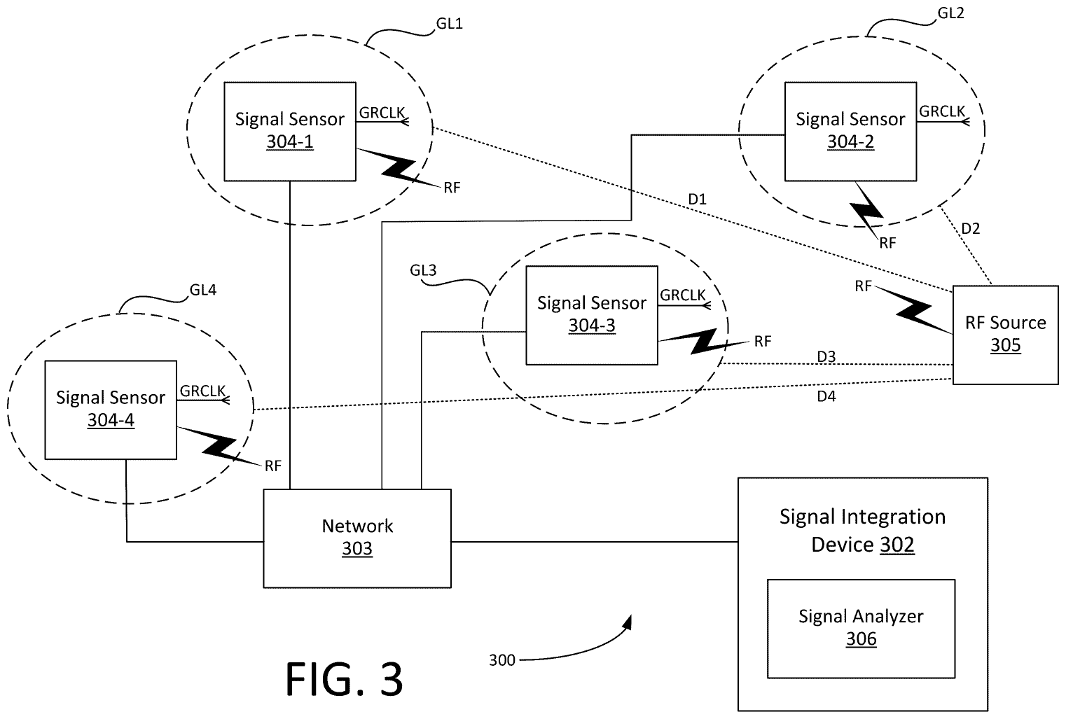

Assuming the GRCLK signal is received by each signal sensor 104 at the same time, the above approach enables a timing offset TO to be determined for each signal sensor relative to a detected transition of the GRCLK signal and thus the timing offsets TO for each of the signal sensors 104 allow the signal analyzer to synchronize or time-align the samples of the RF test signal from all of the signal sensors. As illustrated in the example of FIG. 2, however, the GRCLK signal may not be received by each signal sensor 104 at exactly the same time. FIG. 2 shows that the GRCLK signal is received by signal sensor 104-1 at time t2 while the GRCLK signal is received by signal sensor 104-2 at time t3. A timing offset GRCTO=(t3−t2) may arise for a variety of different reasons, such as a longer or shorter path of propagation path of a GNSS signal forming the GRCLK signal, as well as delays in propagation through a medium such as transmission lines of different lengths between a source of the GRCLK signal and each of the signal sensors 104. Where the GRCLK signal is not received by the signal sensors 104 at the same time, a user of the test and measurement system 100 must know or have a way of determining the timing offsets GRCTO for the GRCKL signal for all the signal sensors 104. This determination is discussed in more detail below with reference to FIG. 3.

FIG. 3 is a block diagram of a test and measurement system 300 according to embodiments including a signal integration device 302 coupled through a network 303 to multiple geographically distributed signal sensors 304-1 to 304-4. The signal sensors 304-1 to 304-4 in FIG. 3 represent geographically distributed signal sensors at respective different geographical locations GL1-GL4 to capture an RF test signal transmitted from an RF signal source 305. The respective geographical locations GL1-GL4 of the signal sensors 304-1 to 304-4 are positioned at different distances D1-D4 from the RF signal source 305 as shown in FIG. 3. Where the RF signal source 305 corresponds to, for example, a constellation of satellites providing a GNSS signal as the GRCLK signal, the propagation paths having the different distances D1-D4 between the RF signal source 305 and the signal sensors 304 result in the GRCLK signal arriving at each of the signal sensors at a different time. The different times of arrival for the GRCLK signal at the signal sensors 304 result in timing offsets GRCTO. A user of test and measurement system 300 must know the physical arrangement of the signal sensors 304 and distances D1-D4 to calculate the timing offsets GRCTO for the signals sensor which allow the signal integration device 302 to synchronize or time-align the samples from the signal sensors. A geographical distance of 1 kilometer (km), for example, results in a propagation delay of approximately 3.3 microseconds for an electromagnetic signal propagating through the earth's atmosphere, which is a significant time delay where the signal sensors 304 are sampling the RF test signal at a rate of 0.2 ns per sample (i.e., 5 GHz), for example.

In embodiments of the test and measurement systems 100 and 300, the general reference clock signal GRCLK may be a synchronization signal that is transmitted in a GNSS system such as the GPS system in the United States. The GRCLK signal is transmitted in common view of all the signal sensors 104, 304, meaning all signal sensors are positioned such that may receive the transmitted GRCLK signal. In such embodiments, each of the signal sensors 104, 304 includes GPS receiver circuitry, which may be considered be part of the measurements units 124 as shown for the signal sensor 104-1 in FIG. 1, to receive the GRCLK signal. The GPS receiver circuitry in each signal sensor 104, 304 receives the GRCLK signal and generates a corresponding synchronization signal internal to the signal sensor that may then be utilized for time-alignment of the samples of the RF test signal captured by the signal sensor. Typical GPS receiver circuitry may, for example, in response to the received GRCLK signal generate a one pulse per second (PPS) signal internal to the signal sensor 104, 304 that is then utilized by the signal sensor 104, 304 for time-alignment of the captured samples of the RF test signal. In FIG. 2, the illustrated GRCLK signal corresponds to the internal 1 PPS signal generated signal by a GPS receiver circuitry in embodiments where the test and measurement systems 100, 300 utilize a GNSS system in time-aligning samples of the RF test signal captured by the multiple signal sensors 104, 304.

As mentioned above, the GRCLK signal may be provided by different sources in further embodiments of the test and measurement systems 100, 300. For example, a signal distribution system may be coupled to each of the signal sensors to distribute the GRCLK signal. The signal distribution system may, for example, include wires, coaxial cables, fiber optic cables, or other suitable transmission media to supply the GRCLK signal to each of the signal sensors 104, 304. A signal distribution system may be utilized in a test lab environment setting as previously mentioned but may also be utilized in setting where the signals sensors 304 are geographically distributed but the GNSS system is not available. War game environments, for example, may include the jamming of the GNSS system being utilized in the region and thus, in such a situation, the standard GNSS system would not be available for use with the signal sensors 304. The GRCLK signal supplied by the signal distribution system in such embodiments may be viewed as an external trigger signal, with the signal sensors 104, 304 and integration devices 102, 302 using this external trigger signal in synchronizing samples captured by the signal sensors as described above with reference to FIGS. 1-3. Such an external trigger signal may be an analog or digital signal and may be transmitted through suitable cabling or through a wireless signal transmitted in common view of all the signals sensors 104, 304. Where the trigger signal is a digital signal, the trigger signal may be an Inter-Range Instrument Group (IRIG) time code signal in embodiments of the systems 100, 300.

In some embodiments, the GRCLK signal may also be utilized in synchronizing the ICLK generators 109 contained in each of the signal sensors 104 illustrated in FIG. 1. In such embodiments, the GRCLK signal is also supplied to the ICLK generator 109 and is used in controlling the frequency of the generated ICLK signal. The frequency of ICLK signal controls the rate at which the sample counter 108 in each signal sensor 104, 304 is clocked and ideally this frequency is maintained at the desired rate to ensure the RF test signal is sampled at the desired sampling rate of the signal sensor. In embodiments of the test and measurement systems 100, 300, the GRCLK signal is an external sinusoidal signal applied to each of the signal sensors 104, 304. In further embodiments, each of the signal sensors 104, 304 includes the ICLK generator that may be synchronized by the GRCLK signal supplied to the signal sensor where the GRCLK signal is a signal according to the Network Time Protocol (NTP). Once the various samples have been time-aligned, using the techniques described above, the aggregated, time-aligned signal may be analyzed and displayed by the signal analyzer 306.

FIG. 4 is a flowchart illustrating an example process 400 of capturing, time-aligning, and displaying samples of an RF test signal from multiple signal sensors 104, 304 as shown in FIGS. 1 and 3 in accordance with embodiments of the present disclosure. The process 400 is described with reference to FIG. 1 but may also be implemented in the system 300 of FIG. 3. The process 400 begins at operation 402 by clocking, in each of the plurality of signal sensors 104, the free-running sample counter 108 to sequentially generate sample counts SCNT. Each of the sequentially generated sample counts SCNT is used in generating a corresponding internal time stamp. The process 400 then proceeds to operation 404 and acquires, in each of the plurality of signal sensors 104, samples of the RF test signal. As described above, each individual sensor 104-1 to 104-4 may sample different or overlapping frequency bands from the same RF signal. The process 400 then moves to operation 406 and associates, in each of the plurality of signal sensors 104, an internal time stamp with each of the samples of the RF test signal. The process 400 then proceeds to operation 408 and detects, in each of the plurality of signal sensors 104, a transition of the GRCLK signal and operation 410 and associates, in each of the plurality of signal sensors 104, one of the internal time stamps to the detected transition of the GRCLK signal.

From operation 410 the process 400 moves to operation 412 and determines, for each of the plurality of signal sensors 104, a timing offset TO1, TO2 (FIG. 2) based on the internal time stamp associated with the detected transition of the GRCLK signal and an internal time stamp associated with a first sample of the RF test signal as discussed above with reference to FIG. 2. The process 400 then proceeds to operation 414 and aggregates samples of the RF test signal and associated internal time stamps along with the internal time stamp associated with the detected transition of the GRCLK signal from the plurality of signal sensors 104. These samples of the RF test signal and associated internal time stamps along with the internal time stamp associated with the detected transition of the GRCLK signal communicated over the network 103 and aggregated by the signal analyzer 106 in the integration device 102 in the system 100. The process 400 thereafter proceeds to operation 416 and the signal analyzer 106 time-aligns the samples of the RF test signal from the plurality of signal sensors 104 using the determined timing offsets TO. Finally, the process 400 goes to operation 418 and the signal analyzer 106 displays the time-aligned samples of the RF test signal from the plurality of signal sensors 104 on a display portion of the user interface 154. In some embodiments, where the sensor signal integration device 102 is also a test and measurement instrument, the user may then analyze the time-aligned samples.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

### EXAMPLES

Example 1 is a system for capturing and analyzing a test signal, the system including a plurality of signal sensors, each of the plurality of signal sensors configured to sample the test signal received by a respective signal sensor and to associate a respective internal time stamp with the test signal sample, and each of the plurality of signal sensors being further configured to receive a general reference clock signal and to associate the respective internal time stamp with a transition of the general reference clock signal, the internal time stamps of each of the plurality of signal sensors being independent of the internal times stamps of the other signal sensors of the plurality of signal sensors; and an integration device coupled to the plurality of signal sensors, the integration device including a signal sensor analyzer configured to time-align the samples of the plurality of signal sensors based on a timing offset determined for each signal sensor from the corresponding internal time stamp associated with the reference clock signal and internal time stamps associated with corresponding samples of the test signal from others of the plurality of signal sensors, and the integration device further configured to display the time-aligned samples of the test signal based on the determined timing offsets.

Example 2 is a system according to Example 1, wherein each of the signal sensors further comprises a sample counter configured to sequentially generate sample counts in response to an internal clock signal, the generated sample counts being utilized in generating the corresponding internal time stamps.

Example 3 is a system according to Example 2, wherein the sample counter is a 64-bit counter, and the internal clock signal is a 5 GHz clock signal.

Example 4 is a system according to any of the preceding Examples, wherein each of the signal sensors includes an internal clock signal generator configured to generate the internal clock signal.

Example 5 is a system according to Example 4, wherein each of the internal clock signal generators is configured to generate its respective internal clock signal based on the general reference clock signal received by the signal sensor.

Example 6 is a system according to any of the preceding Examples, wherein the general reference clock signal is a Global Navigation Satellite System (GNSS) signal.

Example 7 is a system according to any of the preceding Examples, wherein each of the plurality of signal sensors is configured, upon detection of a trigger event, to sample the test signal and is further configured to associate an internal time stamp with detection of the trigger event.

Example 8 is a system according to any of the preceding Examples, wherein each of the plurality of signal sensors comprises a spectrum analyzer.

Example 9 is a system according to any of the preceding Examples, wherein each of the plurality of signal sensors is located at a different geographical location.

Example 10 is a system according to any of the preceding Examples, wherein the test signal is a radio frequency (RF) radar signal.

Example 11 is a system according to any of the preceding Examples, wherein the integration device is coupled through a network to receive the samples of the test signal along with the associated internal time stamps of the samples from each of the signal sensors.

Example 12 is a system according to any of the preceding Examples, wherein the integration device comprises a computer.

Example 13 is a system according to Example 12, wherein the computer comprises one or more processors configured to execute software instructions to implement the signal sensor analyzer, the signal sensor analyzer configured to aggregate the test signal sample from each of the plurality of signal sensors and the internal time stamps associated with these samples, determine, for each of the plurality of signal sensors, the timing offset from the corresponding internal time stamp associated with the reference clock signal and the internal time stamp associated with a first one of the corresponding test signal samples, time-align the samples from the plurality of signal sensors using the determined timing offsets for each of the plurality of signal sensors, and render the time-aligned samples of the test signal on a display of the integration device.

Example 14 is a system according to Example 13, wherein the signal sensor analyzer is further configured to determine the timing offset for each of the plurality of signal sensors by subtracting the internal time stamp associated with the first one of the corresponding samples of the test signal from the internal time stamp associated with the corresponding reference clock signal.

Example 15 is a system for capturing and analyzing a test signal, the system including a plurality of signal sensors, each of the plurality of signal sensors configured, in response to detection of a trigger event of a test signal received by the signal sensor, to sample the test signal and to associate an internal time stamp with each test signal sample, and each of the plurality of signal sensors being further configured to receive a general reference clock signal and to associate an internal time stamp with a transition of the general reference clock signal, the internal time stamps of each of the plurality of signal sensors being independent of the internal time stamps of the other signal sensors of the plurality of signal sensors, and a signal analyzer including an integration device coupled to the plurality of signal sensors, the signal analyzer configured to time-align the samples of the plurality of signal sensors based on a timing offset determined for each signal sensor from the corresponding internal time stamp associated with the reference clock signal and the internal time stamps associated with the test signal samples, and the signal analyzer further configured to display the time-aligned samples of the test signal based on the determined timing offsets.

Example 16 is a system according to Example 15, wherein the trigger event of the test signal is one of envelope, burst, or edge triggering on the test signal.

Example 17 is a system according to any of the Examples 15-16, wherein detection of the trigger event comprises analyzing a trigger signal received from outside the respective signal sensor.

Example 18 is a system according to any of the Examples 15-17, wherein the general reference clock signal is one of a Global Navigation Satellite System (GNSS) signal, a trigger reference signal from a trigger distribution system, or an internal synchronized reference clock signal generated in each of the signal sensors.

Example 19 is a system according to any of the Examples 15-18, wherein each of the plurality of signal sensors is located at a different geographical location and wherein the test signal is a radio frequency (RF) radar signal.

Example 20 is a method for capturing and analyzing a test signal, including clocking, in each of a plurality of signal sensors, a free-running sample counter to sequentially generate sample counts, each of the sequentially generated sample counts being used in generating a corresponding internal time stamp, acquiring, in each of the plurality of signal sensors, samples of the test signal, associating, in each of the plurality of signal sensors, an internal time stamp with each of the samples of the test signal, detecting, in each of the plurality of signal sensors, a transition of a general reference clock signal, associating, in each of the plurality of signal sensors, one of the internal time stamps with the detected transition of the reference clock signal, determining, for each of the plurality of signal sensors, a timing offset based on the internal time stamp associated with the detected transition of the reference clock signal and an internal time stamp associated with a first sample of the test signal, aggregating samples of the test signal and associated internal time stamps along with the internal time stamp associated with the detected transition of the reference clock signal from the plurality of signal sensors, time-aligning the samples of the test signal from the plurality of signal sensors using the determined timing offsets, and displaying the time-aligned samples of the test signal from the plurality of signal sensors.

Example 21 is a method according to Example 20, wherein clocking, in each of a plurality of signal sensors, the free-running sample counter comprises applying an internal clock signal to the corresponding free-running sample counter, the sample counts generated by the free-running sample counter in each of the plurality of signal sensors being independent of the sample counts generated by the free-running sample counters in the other signal sensors of the plurality of signal sensors.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A system for capturing and analyzing a test signal, the system comprising:
a plurality of signal sensors, each of the plurality of signal sensors configured to sample the test signal received by a respective signal sensor and to associate a respective internal time stamp with the test signal sample, and each of the plurality of signal sensors being further configured to receive a general reference clock signal and to associate the respective internal time stamp with a transition of the general reference clock signal, the internal time stamps of each of the plurality of signal sensors being independent of the internal times stamps of the other signal sensors of the plurality of signal sensors; and
an integration device coupled to the plurality of signal sensors, the integration device including a signal sensor analyzer configured to time-align the samples of the plurality of signal sensors based on a timing offset determined for each signal sensor from the corresponding internal time stamp associated with the reference clock signal and internal time stamps associated with corresponding samples of the test signal from others of the plurality of signal sensors, and the integration device further configured to display the time-aligned samples of the test signal based on the determined timing offsets.

2. The system of claim 1, wherein each of the signal sensors further comprises a sample counter configured to sequentially generate sample counts in response to an internal clock signal, the generated sample counts being utilized in generating the corresponding internal time stamps.

3. The system of claim 2, wherein the sample counter is a 64-bit counter, and the internal clock signal is a 5 GHz clock signal.

4. The system of claim 2, wherein each of the signal sensors includes an internal clock signal generator configured to generate the internal clock signal.

5. The system of claim 4, wherein each of the internal clock signal generators is configured to generate its respective internal clock signal based on the general reference clock signal received by the signal sensor.

6. The system of claim 1, wherein the general reference clock signal is a Global Navigation Satellite System (GNSS) signal.

7. The system of claim 1, wherein each of the plurality of signal sensors is configured, upon detection of a trigger event, to sample the test signal and is further configured to associate an internal time stamp with detection of the trigger event.

8. The system of claim 1, wherein each of the plurality of signal sensors comprises a spectrum analyzer.

9. The system of claim 1, wherein each of the plurality of signal sensors is located at a different geographical location.

10. The system of claim 1, wherein the test signal is a radio frequency (RF) radar signal.

11. The system of claim 1, wherein the integration device is coupled through a network to receive the samples of the test signal along with the associated internal time stamps of the samples from each of the signal sensors.

12. The system of claim 1, wherein the integration device comprises a computer.

13. The system of claim 12, wherein the computer comprises one or more processors configured to execute software instructions to implement the signal sensor analyzer, the signal sensor analyzer configured to:
aggregate the test signal sample from each of the plurality of signal sensors and the internal time stamps associated with these samples;
determine, for each of the plurality of signal sensors, the timing offset from the corresponding internal time stamp associated with the reference clock signal and the internal time stamp associated with a first one of the corresponding test signal samples;
time-align the samples from the plurality of signal sensors using the determined timing offsets for each of the plurality of signal sensors; and
render the time-aligned samples of the test signal on a display of the integration device.

14. The system of claim 13, wherein the signal sensor analyzer is further configured to determine the timing offset for each of the plurality of signal sensors by subtracting the internal time stamp associated with the first one of the corresponding samples of the test signal from the internal time stamp associated with the corresponding reference clock signal.

15. A system for capturing and analyzing a test signal, the system comprising:
a plurality of signal sensors, each of the plurality of signal sensors configured, in response to detection of a trigger event of a test signal received by the signal sensor, to sample the test signal and to associate an internal time stamp with each test signal sample, and each of the plurality of signal sensors being further configured to receive a general reference clock signal and to associate an internal time stamp with a transition of the general reference clock signal, the internal time stamps of each of the plurality of signal sensors being independent of the internal time stamps of the other signal sensors of the plurality of signal sensors; and
a signal analyzer including an integration device coupled to the plurality of signal sensors, the signal analyzer configured to time-align the samples of the plurality of signal sensors based on a timing offset determined for each signal sensor from the corresponding internal time stamp associated with the reference clock signal and the internal time stamps associated with the test signal samples, and the signal analyzer further configured to display the time-aligned samples of the test signal based on the determined timing offsets.

16. The system of claim 15, wherein the trigger event of the test signal is one of envelope, burst, or edge triggering on the test signal.

17. The system of claim 15 wherein detection of the trigger event comprises analyzing a trigger signal received from outside the respective signal sensor.

18. The system of claim 15, wherein the general reference clock signal is one of a Global Navigation Satellite System (GNSS) signal, a trigger reference signal from a trigger distribution system, or an internal synchronized reference clock signal generated in each of the signal sensors.

19. The system of claim 15, wherein each of the plurality of signal sensors is located at a different geographical location and wherein the test signal is a radio frequency (RF) radar signal.

20. A method for capturing and analyzing a test signal, the method comprising:
clocking, in each of a plurality of signal sensors, a free-running sample counter to sequentially generate sample counts, each of the sequentially generated sample counts being used in generating a corresponding internal time stamp;
acquiring, in each of the plurality of signal sensors, samples of the test signal;
associating, in each of the plurality of signal sensors, an internal time stamp with each of the samples of the test signal;
detecting, in each of the plurality of signal sensors, a transition of a general reference clock signal;
associating, in each of the plurality of signal sensors, one of the internal time stamps with the detected transition of the reference clock signal;
determining, for each of the plurality of signal sensors, a timing offset based on the internal time stamp associated with the detected transition of the reference clock signal and an internal time stamp associated with a first sample of the test signal;
aggregating samples of the test signal and associated internal time stamps along with the internal time stamp associated with the detected transition of the reference clock signal from the plurality of signal sensors;
time-aligning the samples of the test signal from the plurality of signal sensors using the determined timing offsets; and
displaying the time-aligned samples of the test signal from the plurality of signal sensors.

21. The method of claim 20, wherein clocking, in each of a plurality of signal sensors, the free-running sample counter comprises applying an internal clock signal to the corresponding free-running sample counter, the sample counts generated by the free-running sample counter in each of the plurality of signal sensors being independent of the sample counts generated by the free-running sample counters in the other signal sensors of the plurality of signal sensors.
